(19) United States
(12) Patent Application Publication
(10) Pub. No.: US 2020/0304101 A1
(43) Pub. Date: Sep. 24, 2020

(54) SAW FILTER

(71) Applicant: WISOL CO., LTD., Osan-si (KR)

(72) Inventors: Moon Han CHOI, Osan-si (KR); Jung Do HA, Osan-si (KR); Wan Sub SHIN, Osan-si (KR); Se Yun HAN, Osan-si (KR)

(21) Appl. No.: 16/789,605

(22) Filed: Feb. 13, 2020

(30) Foreign Application Priority Data
Mar. 20, 2019 (KR) 10-2019-0031837

(51) Int. Cl. H03H 9/64; H03H 9/145; H03H 9/25; H03H 7/01; H03H 7/46

(52) U.S. Cl. CPC H03H 9/6483; H03H 9/14502; H03H 7/461; H03H 7/1766; H03H 9/25

(57) ABSTRACT

A SAW filter with an antenna and a transmission terminal includes: a plurality of series resonator groups which are connected in series between the antenna and the transmission terminal; a plurality of parallel resonator groups which are connected in parallel between two neighbor series resonator groups among the plurality of series resonator groups; a parallel inductor which is connected in parallel with the series resonator group adjacent to the antenna; and a series inductor which is connected to in series with some parallel resonator groups among the plurality of parallel resonator groups. The SAW filter has high durability in which even though high power is applied to the filter together with the wide pass band, the filter is not damaged.

### CROSS REFERENCE TO RELATED APPLICATION

This application claims priority from Korean Patent Application No. 10-2019-0031837, filed on Mar. 20, 2019, which is hereby incorporated by reference for all purposes as if fully set forth therein.

### BACKGROUND OF THE INVENTION

### 1. Field of the Invention

The present invention relates to a SAW filter, and more particularly, to a SAW filter including a plurality of series and parallel SAW resonators, in which inductors are embedded in the series and parallel SAW resonators in series and parallel, so that the SAW filter has good attenuation characteristic, in addition to a wide pass band.

### 2. Description of Related Art

A surface acoustic wave is an acoustic wave traveling along the surface of an elastic substrate. Such an acoustic wave is generated from an electrical signal as a result of piezoelectric effect, and if the electric field of the acoustic wave concentrates around the surface of the substrate, the acoustic wave may interact with conductive electrons of another semiconductor which is put right on the surface of the substrate. A SAW device is formed by substituting an electronic circuit with an electromechanical device by interaction between the surface acoustic wave and the conductive electrons of the semiconductor is a SAW device.

The surface acoustic wave device (referred to as a SAW device) is used as an important component of a mobile communication phone and a base station. The most common type of SAW device is a pass band filter and a resonator.

In general, in the case of a filter package using the SAW device, a pass band can be designed by 3 to 5% at the most relative to an intermediate frequency.

As a demand for the filter package having wider pass band is recently increased, a technology of designing two or more ladder-type SAW filters which are connected in series and parallel with resonators has been disclosed. However, the technology has a problem in that since the number of filters to be provided increases to widen the pass band, the overall size of the filter package becomes large, and thus it is difficult to miniaturize and integrate the filter package.

Accordingly, a new structure for the compact filter package with wider pass band is required.

### SUMMARY OF THE INVENTION

Therefore, one object of the invention is to provide a SAW filter with a wide pass band by forming inductors in series and parallel SAW resonator groups.

Another object of the invention is to provide a SAW filter having durability and power durability, in which even though high power is applied to the filter, the SAW filter is not damaged.

According to one aspect of the invention, there is provided a SAW filter with an antenna and a transmission terminal, the SAW filter including: a plurality of series resonator groups which are connected in series between the antenna and the transmission terminal; a plurality of parallel resonator groups which are connected in parallel between two neighbor series resonator groups among the plurality of series resonator groups; a parallel inductor which is connected in parallel with the series resonator group adjacent to the antenna; and a series inductor which is connected to in series with some parallel resonator groups among the plurality of parallel resonator groups.

Preferably, the plurality of series resonator groups include a first series SAW resonator group which is connected in series with the antenna, a second series SAW resonator group which is connected in series with the first series SAW resonator group, a third series SAW resonator group which is connected in series with the second series SAW resonator group, fourth and fifth series SAW resonator groups which are connected in series with the third series SAW resonator group, and a sixth series SAW resonator group which is connected in series with the fifth series SAW resonator group.

Preferably, the plurality of parallel resonator groups include a first parallel SAW resonator group which is connected in parallel between the first series SAW resonator group and the second series SAW resonator group, a second parallel SAW resonator group which is connected in parallel between the second series SAW resonator group and the third series SAW resonator group, a third parallel SAW resonator group which is connected in parallel between the third series SAW resonator group and the fourth series SAW resonator group, and a fourth parallel SAW resonator group which is connected in parallel between the fifth series SAW resonator group and a sixth series SAW resonator group.

Preferably, the number of the SAW resonators provided in the first to three parallel SAW resonator groups is more than that of the SAW resonators provided in the fourth parallel SAW resonator groups.

Preferably, the first to sixth series SAW resonator groups or the first to fourth parallel SAW resonator groups are composed of at least one SAW resonator.

Preferably, the parallel inductor is connected in parallel with the first series SAW resonator group.

Preferably, the series inductor includes a first series inductor which is connected in series between the first parallel SAW resonator group and the ground terminal, a second series inductor which is connected in series between the third parallel SAW resonator group and the ground terminal, and a third series inductor which is connected in series between the fourth parallel SAW resonator group and the ground terminal.

Preferably, a coil pattern of the third series inductor has the number of turns more than that of the coil pattern of the parallel inductor or that of col pattern of the first and second series inductors.

Preferably, the series SAW resonator group and the parallel SAW resonator group include an IDT electrode and a reflector, of which a pattern period of the IDT electrode, a length of a pair of IDT electrodes, or the number of the pair of IDT electrodes is different from each other.

Preferably, the first parallel SAW resonator group connected with the first series inductor and the third parallel SAW resonator group connected with the second series inductor have the same resonant frequency and anti-resonant frequency at a low band.

According to another aspect of the invention, there is provided a SAW filter with an antenna and a transmission terminal, the SAW filter including: a plurality of series resonator groups which are connected in series between the antenna and the transmission terminal; a plurality of parallel resonator groups which are connected in parallel with at least one series resonator groups, among the plurality of series resonator groups, between the antenna and the transmission terminal; a parallel inductor which is connected in parallel with the series resonator group adjacent to the antenna; and a series inductor which is connected to in series with some parallel resonator groups among the plurality of parallel resonator groups.

Preferably, the plurality of series resonator groups include a first series SAW resonator group which is connected in series with the antenna, a second series SAW resonator group which is connected in series with the first series SAW resonator group, a third series SAW resonator group which is connected in series with the second series SAW resonator group, and a fourth series SAW resonator group which is connected in series with the third series SAW resonator group.

Preferably, the plurality of parallel resonator groups include a first parallel SAW resonator group which is connected in series between the antenna and the first series SAW resonator group, a second parallel SAW resonator group which is connected in parallel between the first series SAW resonator group and the second series SAW resonator group, a third parallel SAW resonator group which is connected in parallel between the second series SAW resonator group and the third series SAW resonator group, and a fourth parallel SAW resonator group which is connected in parallel between the third series SAW resonator group and the fourth series SAW resonator group.

With the configuration of the SAW filter according to the invention, the inductor is connected to the series SAW resonator group which is disposed to the antenna, and the inductors having different inductance value are connected between the parallel SAW inductor and the ground terminal, thereby widening the pass band of the SAW filter, improving the attenuation characteristic, and decreasing the insertion loss.

Also, since a plurality of filter layers are not required to widen the pass band, it is possible to miniaturize the overall size of the SAW filter.

In addition, since the number of the inductors to be connected with the series and parallel SAW resonator groups is differently set, even though the high power is applied to the SAW filter, the SAW filter is not damaged, that is, the SAW filter has power durability.

### BRIEF DESCRIPTION OF THE DRAWINGS

Reference is now made briefly to the accompanying drawings, in which:

FIG. 1 is a circuit diagram illustrating a SAW filter according to the first embodiment of the invention;

FIG. 2 is a circuit diagram illustrating a SAW filter according to the second embodiment of the invention;

FIG. 3 is a circuit diagram illustrating a SAW filter according to the third embodiment of the invention;

FIG. 4 is a circuit diagram illustrating a SAW filter according to the fourth embodiment of the invention;

FIG. 5 is a circuit diagram illustrating a SAW filter according to the fifth embodiment of the invention;

FIG. 6 is a circuit diagram illustrating a SAW filter according to the sixth embodiment of the invention;

FIG. 7 is a circuit diagram illustrating a SAW filter according to the seventh embodiment of the invention;

FIG. 8 is a graph illustrating a frequency characteristic of a section A in FIG. 1;

FIG. 9 is a graph illustrating a frequency characteristic of a section B in FIG. 1;

FIG. 10 is a graph illustrating a frequency characteristic of a section C in FIG. 1;

FIG. 11 is a graph illustrating a frequency characteristic of a section D in FIG. 1;

FIG. 12 is a graph illustrating a pass band of the SAW filter according to the first to seventh embodiments of the invention;

FIG. 13 is a graph illustrating a VSWR characteristic of an antenna side according to the first to seventh embodiments of the invention; and

FIG. 14 is a graph illustrating a VSWR characteristic of a transmission terminal side according to the first to seventh embodiments of the invention.

### DETAILED DESCRIPTION OF THE PREFERRED EMBODIMENTS

Hereinafter, preferred embodiments of the invention will be described in detail with reference to the accompanying drawings. Advantages and features of the invention and a method for achieving the same will be more clearly understood with reference to the embodiments described below, together with the accompanying drawings. However, the invention is not limited to the embodiments disclosed below, but may be implemented in various different forms. The embodiments are provided merely to complete disclosure of the invention and to fully provide a person having ordinary skill in the art to which the invention pertains with the category of the invention. The invention is defined only by the category of the claims. Wherever possible, the same reference numbers will be used throughout the specification to refer to the same or like parts.

Unless otherwise defined, all terms used in this specification (including technical and scientific terms) may be used as a meaning that can be commonly understood by those skilled in the art. In addition, the terms defined in a generally used dictionary are not to be ideally or excessively interpreted unless the terms are clearly and specially defined. The terms used in this specification are not to limit the invention, but to describe the embodiments. In this specification, singular forms are intended to include plural forms as well, unless the context clearly indicates otherwise.

The terms “comprises” and/or “comprising” used herein specify that the stated components, steps, operations and/or elements do not preclude the presence or addition of one or more other components, steps, operations and/or elements.

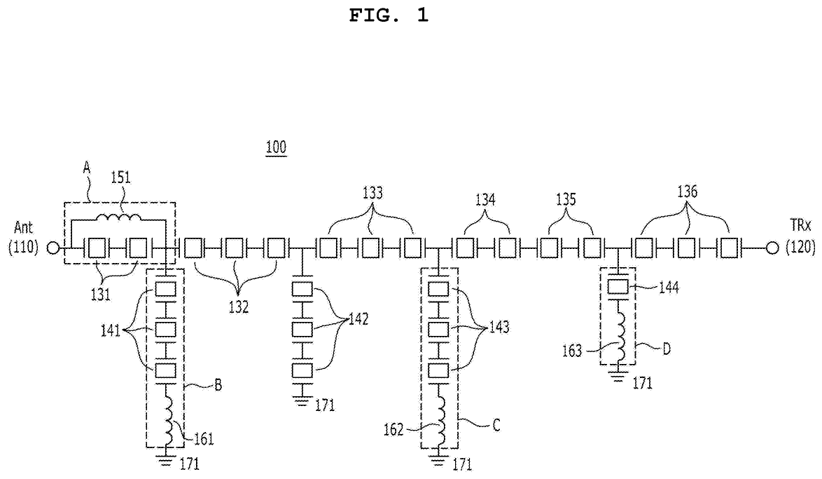

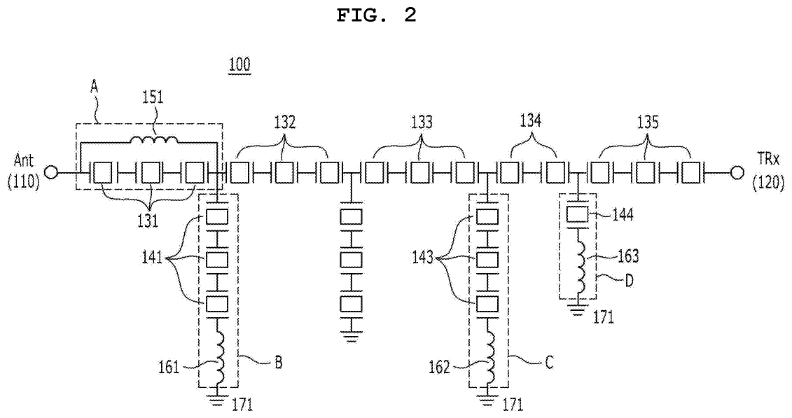

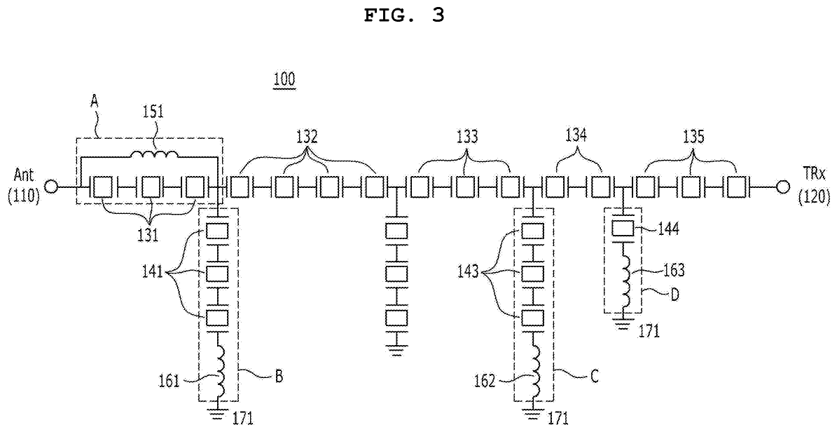

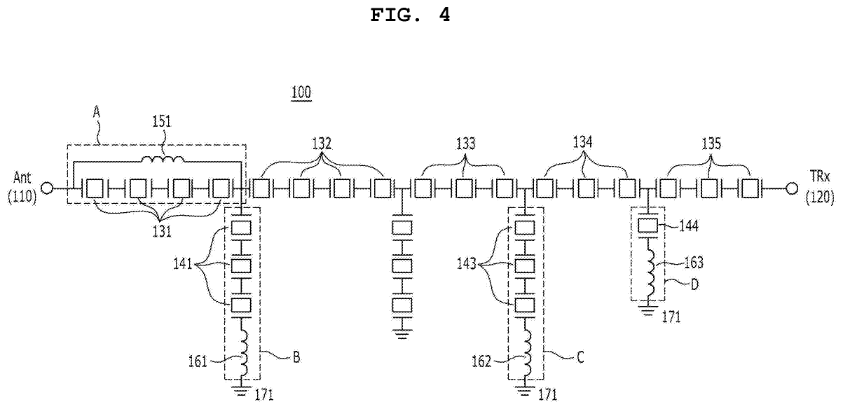

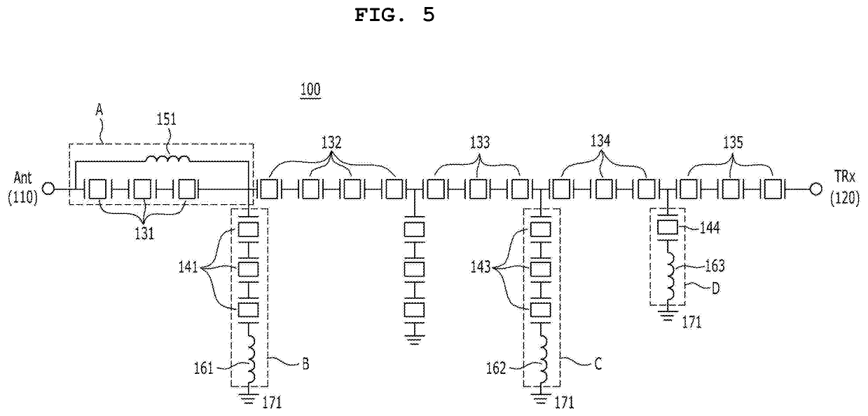

FIG. 1 is a circuit diagram illustrating a SAW filter 100 according to the first embodiment of the invention. FIG. 2 is a circuit diagram illustrating a SAW filter 100 according to the second embodiment of the invention. FIG. 3 is a circuit diagram illustrating a SAW filter 100 according to the third embodiment of the invention. FIG. 4 is a circuit diagram illustrating a SAW filter 100 according to the fourth embodiment of the invention. FIG. 5 is a circuit diagram illustrating a SAW filter 100 according to the fifth embodiment of the invention.

The SAW filters 100 illustrated in FIGS. 1 to 5 include the same connecting structure between series and parallel resonator groups and inductors, but only the number of the resonators forming the group of resonators is different from each other. Accordingly, it would be apparent from those skilled in the art that description of the first embodiment in FIG. 1 is substantially identical to that of the second to fifth embodiments.

Referring to FIG. 1, the SAW filter 100 of the invention includes an antenna 110, a transmission terminal 120, series SAW resonator groups 131 to 136, parallel SAW resonator groups 141 to 144, a parallel inductor 151, series inductors 161 to 163 and a ground terminal 171.

More specifically, the antenna 110 transmits a signal to a base station, or sends the received signal to other chip connected to the SAW filter 100. The SAW filter 100 may be provided to a mobile communication terminal, and may include various antennas which are commercially available. For example, the antenna 110 includes a retractable-type antenna, a stubby-type antenna using a stationary antenna head, and a built-in-type antenna which does not protrude outwardly. Also, the antenna 110 includes various antennas for the mobile communication terminal, for example, a monopole antenna, a helical antenna, a ceramic ship antenna, a chip antenna, and an inverted-F strip antenna.

The transmission terminal 120 is configured to transmit or receive a signal to or from various chips which are connected to the SAW filter 100, and may be connected in series with the antenna 110.

A plurality of series resonator groups and a plurality of parallel resonator groups may be provided between the antenna 110 and the transmission terminal 120 which are connected in series. All of the series and parallel resonator groups may be a SAW resonator using the SAW device. Specifically, the SAW filter 100 of the invention may be a ladder type including series resonator groups having a plurality of series SAW resonators, and parallel resonator groups having a plurality of parallel SAW resonators.

In the drawings, the plurality of series SAW resonator groups 131 to 136 and the plurality of parallel SAW resonator groups 141 to 144 are illustrated as a first series SAW resonator group 131, a second series SAW resonator group 132, a third series SAW resonator group 133, a fourth series SAW resonator group 134, a fifth series SAW resonator group 135, a sixth series SAW resonator group 136, a first parallel SAW resonator group 141, a second parallel SAW resonator group 142, a third parallel SAW resonator group 143 and a fourth parallel SAW resonator group 144.

More specifically, the series resonator groups include the first series SAW resonator group 131 connected in series with the antenna 110, the second series SAW resonator group 132 connected in series with the first series SAW resonator group 131, the third series SAW resonator group 133 connected in series with the second series SAW resonator group 132, the fourth and fifth series SAW resonator groups 134 and 135 connected in series with the third series SAW resonator group 133, and the sixth series SAW resonator group 136 connected in series with the fifth series SAW resonator group 135. The above-described series resonator groups are composed of at least one SAW resonator. More preferably, the first series SAW resonator group 131 includes at least two SAW resonators, the second series SAW resonator group 132 includes at least three SAW resonators, the third series SAW resonator group 133 includes at least three SAW resonators, the fourth and fifth series SAW resonator groups 134 and 135 include at least two SAW resonators, and the sixth series SAW resonator group 136 includes at least three SAW resonators.

Also, the parallel resonator groups include the first parallel SAW resonator group 141 connected in parallel between the first series SAW resonator group 131 and the second series SAW resonator group 132, the second parallel SAW resonator group 142 connected in parallel between the second series SAW resonator group 132 and the third series SAW resonator group 133, the third parallel SAW resonator group 143 connected in parallel between the third series SAW resonator group 133 and the fourth series SAW resonator group 134, and the fourth parallel SAW resonator group 144 connected in parallel between the fifth series SAW resonator group 135 and the sixth series SAW resonator group 136. The above-described parallel SAW resonator groups are composed of at least one SAW resonator, similar to the series resonator groups. More specifically, the first parallel SAW resonator group 141 includes at least three SAW resonators, the second parallel SAW resonator group 142 includes at least three SAW resonators, the third parallel SAW resonator group 143 includes at least three SAW resonators, and the fourth parallel SAW resonator group 144 includes one SAW resonator. That is, the number of SAW resonators provided in the first to third parallel resonator groups 141 to 143 may be more than the number of SAW resonators provided in the fourth parallel SAW resonator groups 144.

The series SAW resonator groups 131 to 136 and the parallel SAW resonator groups 141 to 144 may be composed of an interdigital transducer (referred to as IDT) electrode and a reflector. In this instance, the reflector forming the respective resonator groups may be disposed in the form of an open circuit, in which both ends of the plurality of electrodes are not connected, in the form of a close circuit connecting both ends of the plurality of electrodes, or in the form of a positive and negative (PNR) grating which combines the open circuit form and the close circuit form.

Since the series and parallel SAW resonator groups include the reflector, it is possible to improve reflection characteristic of the respective resonators. More specifically, the reflector can reduce insertion loss of the surface acoustic wave by reflecting the surface acoustic wave which propagates along the IDT electrode.

Meanwhile, in order to widen the pass band of the SAW filter 100, the series SAW resonator groups 131 to 136 and the parallel SAW resonator groups 141 to 144 are set in such a way that a pattern period of the IDT electrode, a length of a pair of IDT electrodes, the number of the pair of IDT electrodes, or the number of the reflector, which is provided to the series and parallel SAW resonator groups, is different from each other, which will be described in detail hereinafter.

For descriptive convenience, the section of the parallel resonator groups, with which the inductor is connected, will now be described by making a division, such as a section A, a section B, a section C and a section D.

The section A is a region including a parallel inductor 151 connected in parallel with the first series SAW resonator group 131 adjacent to the antenna 110. The section B is a region including a first series inductor 161 connected in series between the first parallel SAW resonator group 141 and the ground terminal 171. The section C is a region including a second series inductor 162 connected in series between the third parallel SAW resonator group 143 and the ground terminal 171. The section D is a region including a third series inductor 163 connected in series between the fourth parallel SAW resonator group 144 and the ground terminal 171.

Specifically, the SAW filter 100 of the invention may include one or more series inductors 161 to 163 connected in series with at least three parallel SAW resonator groups 141 to 144 to improve the frequency characteristic of the SAW filter 100.

The second to fifth embodiments illustrated in FIGS. 2 to 5 will be readily understood by those skilled in the art from the description of the first embodiment illustrated in FIG. 1, and thus the description thereof will be omitted herein.

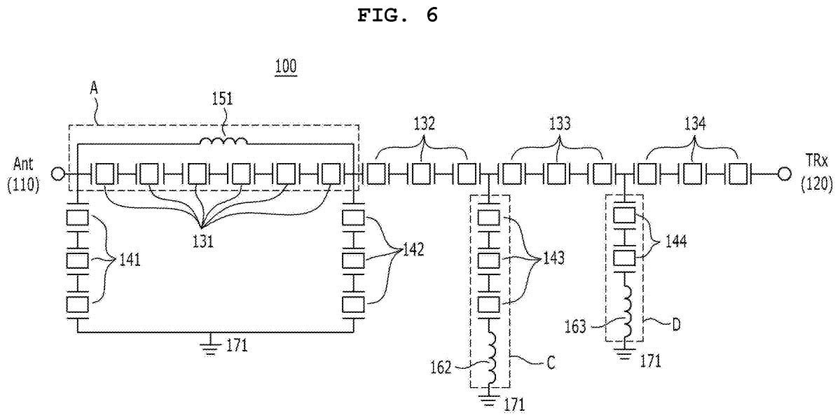

FIG. 6 is a circuit diagram illustrating the SAW filter 100 according to the sixth embodiment of the invention.

The components of the SAW filter 100 illustrated in FIG. 6 are substantially identical to those of the SAW filter 100 illustrated in FIG. 3, and thus it will be described on the basis of the connection structure of the SAW filter 100.

Referring to FIG. 6, the SAW filter 100 of the invention includes an antenna 110, a transmission terminal 120, a plurality of series SAW resonator groups 131 to 134, a plurality of parallel SAW resonator groups 141 to 144, a parallel inductor 151, series inductors 161 to 163 and a ground terminal 171.

More specifically, the plurality of series resonator groups 131 to 134 include the first series SAW resonator group 131 connected in series with the antenna 110, the second series SAW resonator group 132 connected in series with the first series SAW resonator group 131, the third series SAW resonator group 133 connected in series with the second series SAW resonator group 132, and the fourth series SAW resonator group 134 connected in series with the third series SAW resonator group 133. The above-described series resonator groups are composed of at least one SAW resonator. More preferably, the first series SAW resonator group 131 includes six SAW resonators, the second series SAW resonator group 132 includes at least three SAW resonators, the third series SAW resonator group 133 includes at least three SAW resonators, and the fourth series SAW resonator group 134 includes at least three SAW resonators.

Also, the parallel resonator groups include the first parallel SAW resonator group 141 connected in parallel between the antenna 110 and the first series SAW resonator group 131, the second parallel SAW resonator group 142 connected in parallel between the first series SAW resonator group 131 and the second series SAW resonator group 132, the third parallel SAW resonator group 143 connected in parallel between the second series SAW resonator group 132 and the third series SAW resonator group 133, and the fourth parallel SAW resonator group 144 connected in parallel between the third series SAW resonator group 133 and the fourth series SAW resonator group 134. The first parallel SAW resonator group 141 and the second parallel SAW resonator group 142 may be connected in parallel with one ground terminal 171.

The above-described parallel SAW resonator groups are composed of at least one SAW resonator, similar to the series resonator groups. More specifically, the first parallel SAW resonator group 141 includes at least three SAW resonators, the second parallel SAW resonator group 142 includes at least three SAW resonators, the third parallel SAW resonator group 143 includes at least three SAW resonators, and the fourth parallel SAW resonator group 144 includes at least two SAW resonators.

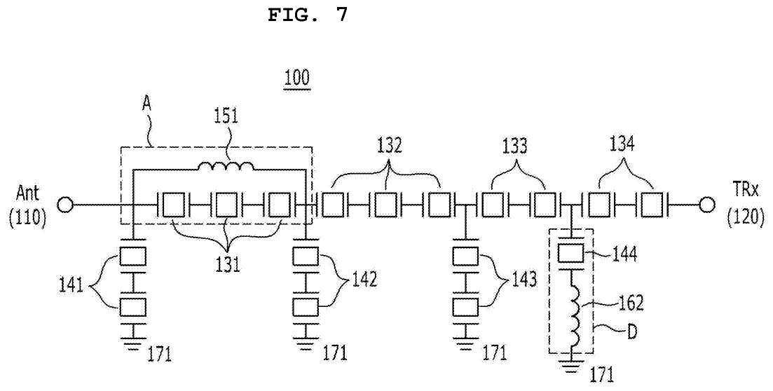

FIG. 7 shows a SAW filter 100 according to the seventh embodiment of the invention. Referring to FIG. 7, the SAW filter 100 of the seventh embodiment includes a first parallel SAW resonator group 141 and a second parallel SAW resonator group 142 which are not connected in parallel with one ground terminal, but are separated from each other.

Also, the SAW filter 100 of the seventh embodiment may include one parallel SAW resonator group connected in series with an inductor. Specifically, the SAW filter 100 having a wide pass band can be realized only by inserting one parallel inductor and one series inductor into the series and parallel resonator groups.

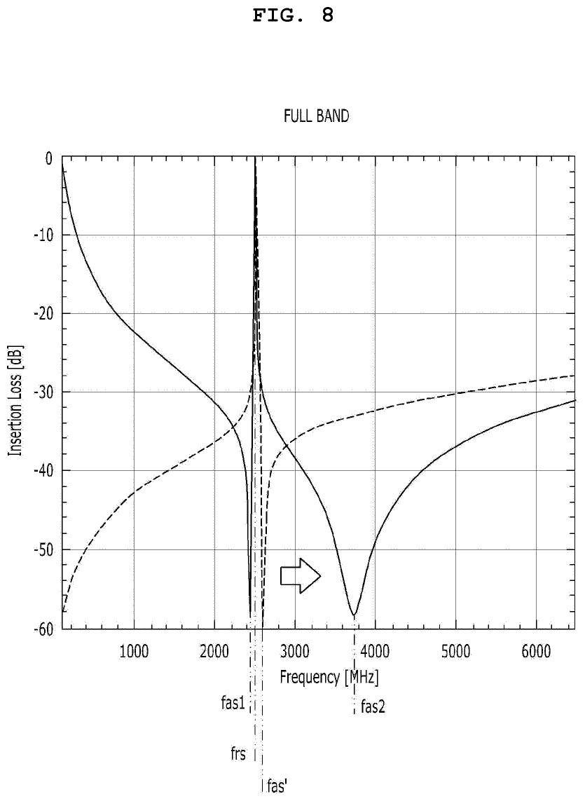

FIG. 8 is a graph illustrating the frequency characteristic of the section A in FIG. 1.

In the drawing, the horizontal axis denotes frequency MHz, the vertical axis denotes insertion loss dB, the solid line denotes an embodiment of the invention in which the parallel inductor 151 is formed, and the dotted line denotes a comparative example in which the parallel inductor 151 is not formed.

Referring to FIG. 8, the frequency characteristic of the section A including the parallel inductor 151 connected in parallel with the first series SAW resonator group 131 which is connected to the antenna 110 is shown below.

Specifically, since the SAE filter 100 of the invention includes the parallel inductor 151 connected in parallel with the first series SAW resonator group 131 adjacent to the antenna 110, one resonant frequency frs and two anti-resonant frequencies fas1 and fas2 can be obtained, and a value of the anti-resonant frequency fas2 at a high band can increase relative to that of an anti-resonant frequency fas′ of the prior art.

More specifically, it would be noted that the value of the anti-resonant frequency fas2 at the high band increases from 2800 MHz to 3600 to 3800 MHz, and as the difference between the anti-resonant frequency fas2 and the resonant frequency frs increases, a value of an electromechanical coupling factor K² increases, and an effect of increasing the pass band of the SAW filter can be obtained.

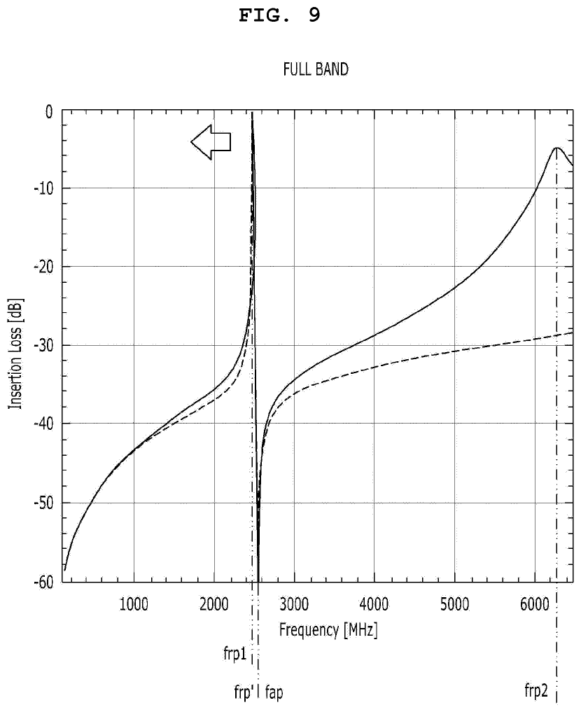

FIG. 9 is a graph illustrating the frequency characteristic of the section B in FIG. 1.

In the drawing, the horizontal axis denotes frequency MHz, the vertical axis denotes insertion loss dB, the solid line denotes an embodiment of the invention in which the series inductor 161 is formed, and the dotted line denotes a comparative example in which the first series inductor 161 is not formed.

Referring to FIG. 9, the frequency characteristic of the section B including the first series inductor 161 connected in series with the first parallel SAW resonator group 141 is shown below.

Specifically, since the SAE filter 100 of the invention includes the parallel inductor 151 connected in series with the first parallel SAW resonator group 141 adjacent to the antenna 110, two resonant frequencies frp1 and frp2 and one anti-resonant frequency fap can be obtained, and a value of the resonant frequency frp1 at a low band can decrease relative to that of a resonant frequency frp′ of the prior art.

More specifically, it would be noted that the value of the resonant frequency frp1 at the low band decreases from 2600 MHz to 2400 to 2500 MHz, and as the difference between the resonant frequency frp1 and the anti-resonant frequency fap increases, a value of an electromechanical coupling factor K² increases, and an effect of increasing the pass band of the SAW filter can be obtained.

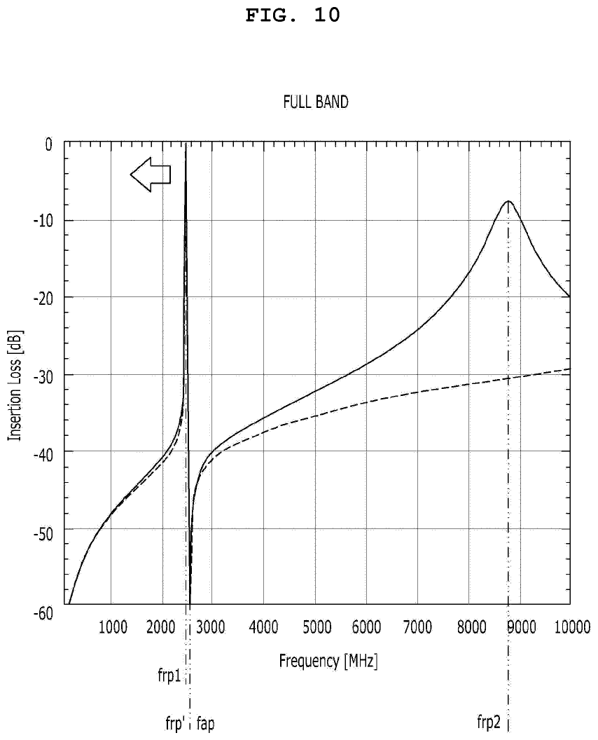

FIG. 10 is a graph illustrating the frequency characteristic of the section A in FIG. 1.

In the drawing, the horizontal axis denotes frequency MHz, the vertical axis denotes insertion loss dB, the solid line denotes an embodiment of the invention in which the second series inductor 162 is formed, and the dotted line denotes a comparative example in which the second series inductor 162 is not formed.

Referring to FIG. 10, the frequency characteristic of the section C including the second series inductor 162 connected in series with the third parallel SAW resonator group 143 is shown below.

Specifically, since the SAE filter 100 of the invention includes the second series inductor 162 connected in series with the third parallel SAW resonator group 143 which is connected in parallel with the third and fourth series SAW resonator groups 133 and 134, two resonant frequencies frp1 and frp2 and one anti-resonant frequency fap can be obtained, and a value of the resonant frequency frp1 at a low band can decrease relative to that of a resonant frequency frp′ of the prior art.

More specifically, it would be noted that the value of the resonant frequency frp1 at the low band increases from 2650 MHz to 2400 to 2500 MHz, and as the difference between the resonant frequency frp1 and the anti-resonant frequency fap increases, a value of an electromechanical coupling factor K² increases, and an effect of increasing the pass band of the SAW filter can be obtained.

As described above, since the section B and the section C have similar decreased width of the resonant frequency at the low band, it would be understood that the resonant frequency and the anti-resonant frequency in the section B and the section C at the low band are equal. Also, since the frequency characteristics of the section B and the section C are equal, an effect of increasing a skirt characteristic of the SAW filter 100 at the low band can be obtained.

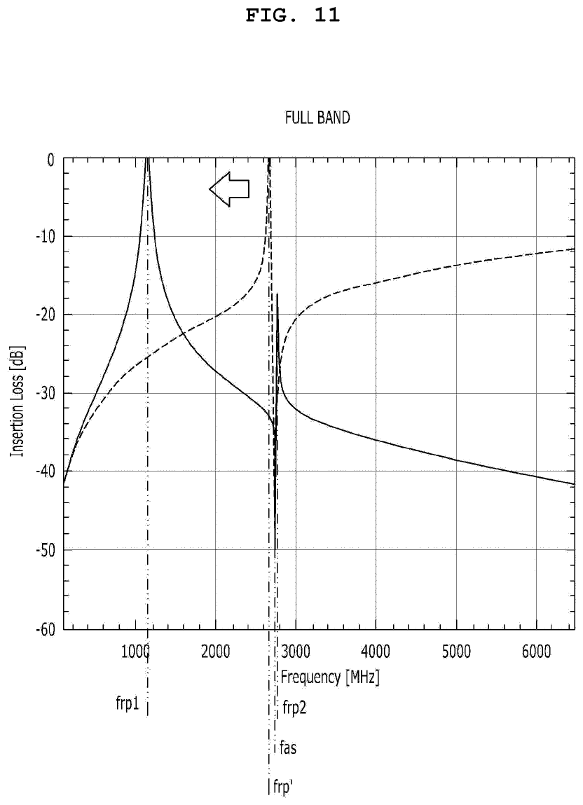

FIG. 11 is a graph illustrating the frequency characteristic of the section D in FIG. 1.

In the drawing, the horizontal axis denotes frequency MHz, the vertical axis denotes insertion loss dB, the solid line denotes an embodiment of the invention in which the third series inductor 163 is formed, and the dotted line denotes a comparative example in which the third series inductor 163 is not formed.

Referring to FIG. 11, the frequency characteristic of the section D including the third series inductor 163 connected in series with the fourth parallel SAW resonator group 144 is shown below.

Specifically, since the SAE filter 100 of the invention includes the third series inductor 163 connected in series with the fourth parallel SAW resonator group 144 which is connected in parallel between the fifth and sixth series SAW resonator groups 135 and 136 adjacent to the transmission terminal 120, two resonant frequencies frp1 and frp2 and one anti-resonant frequency fap can be obtained, and a value of the resonant frequency frp1 at a low band can decrease relative to that of a resonant frequency frp′ of the prior art.

More specifically, it would be noted that the value of the resonant frequency frp1 at the low band increases from 2600 to 2700 MHz to 1000 to 1200 MHz, and as the difference between the resonant frequency frp1 and the anti-resonant frequency fap increases, a value of an electromechanical coupling factor K² increases, and an effect of increasing the pass band of the SAW filter can be obtained.

Meanwhile, a coil pattern forming the parallel inductor 151 and the first to third series inductors 161 to 163 which are provided in the series and parallel SAW resonator groups may be 2 to 4 turns. Also, since the parallel inductor 151 and the first to third series inductors 161 to 163 are simultaneously wound from an upper layer of a layer forming the SAW filter 100, the SAW filter 100 with the enhanced pass band can be minimized.

The coil pattern of the third series inductor 163 may have the number of turns more than that of the coil patterns of the parallel inductor 151 and the first and second series inductors 161 and 162. That is, since an inductance value of the third series inductor 163 adjacent to the transmission terminal 120 become large, the value of the resonant frequency at the low band decreases, and the pass band increases.

The frequency characteristics of the sections A to D in FIGS. 2 to 7 are substantially identical to those of the sections A to D in FIG. 1, and thus the description will be omitted herein.

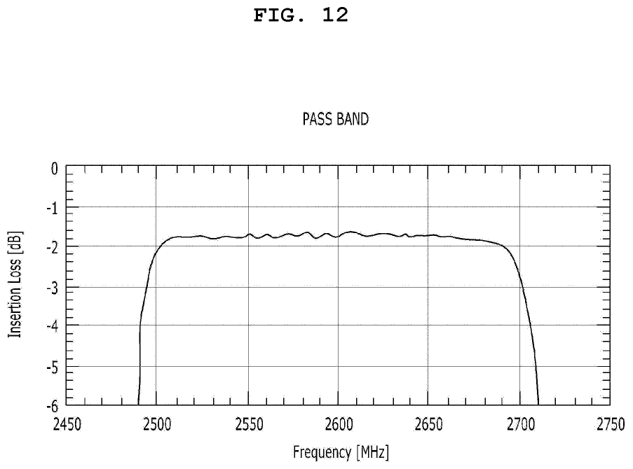

FIG. 12 is a graph illustrating the pass band characteristic of the SAW filter 100 according to the first to seventh embodiments of the invention. In the drawing, the horizontal axis denotes frequency MHz, and the vertical axis denotes insertion loss dB.

Referring to FIG. 12, it would be noted that the SAW filter 100 including the parallel inductor 151 and the series inductors 161 to 163 has the wide pass band of 2500 to 2700 MHz.

Referring to Table 1 below, it would be noted that the SAW filter 100 of the invention has an effect of reducing average and maximum insertion loss at the frequency band of 2500 to 2500 MHz, and a ripple occurring at the pass band decreases, thereby improving the characteristic of the SAW filter 100.

TABLE 1

| | | | Prior Design | | Invention Design | |
|---|---|---|---|---|---|---|
| | Frequency (MHz) | | Typ | Max | Typ | Max |
| IL (dB) | 2496 | 2501 | 2.5 | 4.5 | 2.2 | 4.2 |
| | 2501 | 2690 | 2.4 | 4.5 | 2.5 | 3.1 |
| | 2555 | 2655 | 2.3 | 3.5 | 1.8 | 2.3 |
| | 2545 | 2575 | 2.4 | 3.5 | 1.7 | 2.2 |
| | 2620 | 2690 | 2.3 | 3.5 | 2.1 | 3.0 |
| Ripple | 2496 | 2520 | 1.4 | 2.6 | 0.6 | 1.8 |
| (dB) | 2520 | 2690 | 0.7 | 1.8 | | |

Also, it would be noted that the SAW filter 100 of the invention has an effect of improving an attenuation characteristic from the low band of about 1260 MHz to the frequency of the pass band.

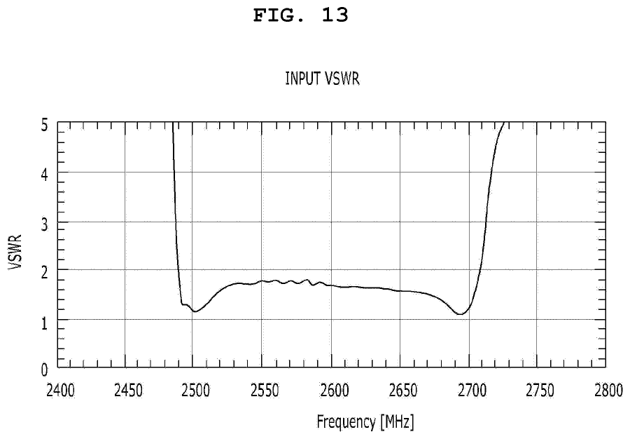

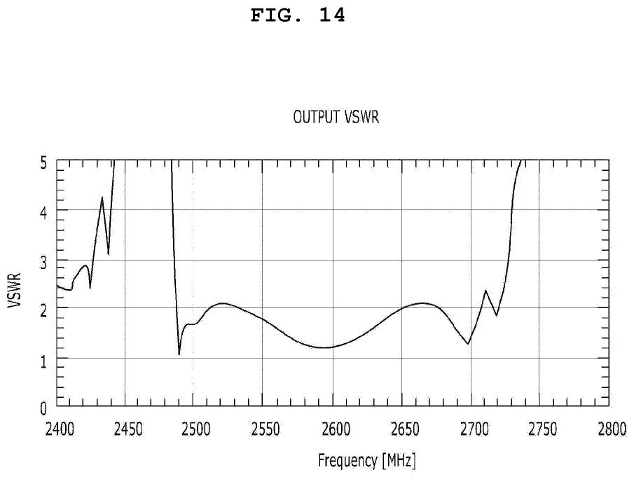

TABLE 2

| | | | Prior Design | | Present Design | |
|---|---|---|---|---|---|---|
| | Frequency (MHz) | | Min | Typ | Min | Typ |
| Attenuation | 1226.57 | 1228.63 | 25 | 39 | 38 | 48 |
| (dB) | 1242.42 | 1249.14 | 25 | 39 | 38 | 48 |
| | 1248 | 1605.89 | 30 | 33 | 30 | 34 |
| | 1615 | 2400 | 15 | 18 | 17 | 30 |
| | 1710 | 1785 | 20 | 27 | 25 | 30 |
| | 1805 | 1850 | 18 | 24 | 21 | 27 |
| | 1880 | 1920 | 18 | 21 | 21 | 25 |
| | 2110 | 2170 | 16 | 19 | 16 | 20 |

[98] FIG. 13 is a graph illustrating a VSWR characteristic of the antenna 110 according to the first to seventh embodiments of the invention. FIG. 14 is a graph illustrating a VSWR characteristic of the transmission terminal 120 according to the first to seventh embodiments of the invention. In the drawings, the horizontal axis denotes frequency MHz, and the vertical axis denotes a voltage standing wave ratio (VSWR).

[99] Referring to FIGS. 13 and 14, in the case of the SAW filter 100, it would be noted that the VSWR value approaches about 1 from the point of about 2500 MHz, and the VSWR value abruptly increases from the point of about 2700 MHz. That is, the SAW filter 100 of the invention has a wide band of frequencies from about 2500 to 2700 MHz which can pass through the filter. The SAW filter 100 according to various embodiments of the invention has been described hereinbefore. According to the invention, since the series and parallel inductors having different inductance value are respectively formed in the series and parallel SAW resonator groups, the SAW filter can have the wide pass band, without enlarging the filter. Also, even though the high power is applied to the filter, the SAW filter is not damaged, and the SAW filter has power durability.

Although embodiments of the invention have been described with reference to the attached drawings, those skilled in the art may understand that the invention can be embodied in other specific forms without changing the technical spirit or essential features thereof. Therefore, it should be understood that the embodiments described above are illustrative, not restrictive, in all aspects.

The invention is not to be restricted by the embodiments but only by the appended claims. It is to be appreciated that those skilled in the art can change or modify the embodiments without departing from the scope and spirit of the invention.

What is claimed is:

1. A SAW filter with an antenna and a transmission terminal, the SAW filter comprising:
a plurality of series resonator groups which are connected in series between the antenna and the transmission terminal;
a plurality of parallel resonator groups which are connected in parallel between two neighbor series resonator groups among the plurality of series resonator groups;
a parallel inductor which is connected in parallel with the series resonator group adjacent to the antenna; and
a series inductor which is connected to in series with some parallel resonator groups among the plurality of parallel resonator groups.

2. The SAW filter according to claim 1, wherein the plurality of series resonator groups include:
a first series SAW resonator group which is connected in series with the antenna,
a second series SAW resonator group which is connected in series with the first series SAW resonator group,
a third series SAW resonator group which is connected in series with the second series SAW resonator group,
fourth and fifth series SAW resonator groups which are connected in series with the third series SAW resonator group, and
a sixth series SAW resonator group which is connected in series with the fifth series SAW resonator group.

3. The SAW filter according to claim 2, wherein the plurality of parallel resonator groups include:
a first parallel SAW resonator group which is connected in parallel between the first series SAW resonator group and the second series SAW resonator group,
a second parallel SAW resonator group which is connected in parallel between the second series SAW resonator group and the third series SAW resonator group,
a third parallel SAW resonator group which is connected in parallel between the third series SAW resonator group and the fourth series SAW resonator group, and
a fourth parallel SAW resonator group which is connected in parallel between the fifth series SAW resonator group and a sixth series SAW resonator group.

4. The SAW filter according to claim 3, wherein the number of the SAW resonators provided in the first to three parallel SAW resonator groups is more than that of the SAW resonators provided in the fourth parallel SAW resonator groups.

5. The SAW filter according to claim 3, wherein the first to sixth series SAW resonator groups or the first to fourth parallel SAW resonator groups are composed of at least one SAW resonator.

6. The SAW filter according to claim 2, wherein the parallel inductor is connected in parallel with the first series SAW resonator group.

7. The SAW filter according to claim 3, wherein the series inductor includes:
a first series inductor which is connected in series between the first parallel SAW resonator group and the ground terminal,
a second series inductor which is connected in series between the third parallel SAW resonator group and the ground terminal, and
a third series inductor which is connected in series between the fourth parallel SAW resonator group and the ground terminal.

8. The SAW filter according to claim 7, wherein a coil pattern of the third series inductor has the number of turns more than that of the coil pattern of the parallel inductor or that of col pattern of the first and second series inductors.

9. The SAW filter according to claim 3, wherein the series SAW resonator group and the parallel SAW resonator group include an IDT electrode and a reflector, of which a pattern period of the IDT electrode, a length of a pair of IDT electrodes, or the number of the pair of IDT electrodes is different from each other.

10. The SAW filter according to claim 6, wherein the first parallel SAW resonator group connected with the first series inductor and the third parallel SAW resonator group connected with the second series inductor have the same resonant frequency and anti-resonant frequency at a low band.

11. A SAW filter with an antenna and a transmission terminal, the SAW filter comprising:
a plurality of series resonator groups which are connected in series between the antenna and the transmission terminal;
a plurality of parallel resonator groups which are connected in parallel with at least one series resonator groups, among the plurality of series resonator groups, between the antenna and the transmission terminal;
a parallel inductor which is connected in parallel with the series resonator group adjacent to the antenna; and
a series inductor which is connected to in series with some parallel resonator groups among the plurality of parallel resonator groups.

12. The SAW filter according to claim 11, wherein the plurality of series resonator groups include:
a first series SAW resonator group which is connected in series with the antenna,
a second series SAW resonator group which is connected in series with the first series SAW resonator group,
a third series SAW resonator group which is connected in series with the second series SAW resonator group, and
a fourth series SAW resonator group which is connected in series with the third series SAW resonator group.

13. The SAW filter according to claim 12, wherein the plurality of parallel resonator groups include:
a first parallel SAW resonator group which is connected in series between the antenna and the first series SAW resonator group,
a second parallel SAW resonator group which is connected in parallel between the first series SAW resonator group and the second series SAW resonator group,
a third parallel SAW resonator group which is connected in parallel between the second series SAW resonator group and the third series SAW resonator group, and
a fourth parallel SAW resonator group which is connected in parallel between the third series SAW resonator group and the fourth series SAW resonator group.
